(19) United States
(12) Patent Application Publication
(10) Pub. No.: US 2016/0293823 A1
(43) Pub. Date: Oct. 6, 2016

(54) Thermoelectric Conversion Module

(71) Applicant: HITACHI CHEMICAL COMPANY, LTD., Chiyoda-ku, Tokyo (JP)

(72) Inventors: Shinichi FUJIWARA, Tokyo (JP); Tomotake TOHEI, Tokyo (JP); Zenzou ISHIJIMA, Tokyo (JP); Takahiro JINUSHI, Tokyo (JP); Masanao TOMINAGA, Tokyo (JP)

(73) Assignee: Hitachi Chemical Company, Ltd., Tokyo (JP)

(21) Appl. No.: 15/037,334

(22) PCT Filed: Mar. 2, 2015
(86) PCT No.: PCT/JP2015/056074

§ 371 Date: May 18, 2016

(30) Foreign Application Priority Data
Mar. 4, 2014 (JP) 2014-041613

(51) Int. Cl. H01L 35/32; H01L 35/08; H01L 35/34

(52) U.S. Cl. CPC H01L 35/32; H01L 35/34; H01L 35/08

(57) ABSTRACT

Provided is a thermoelectric conversion module which achieves, in the vicinity of an element/high-temperature-side electrode bonded part, stress relaxation or strain relaxation within the element and at the bonded part, on which stress is concentrated. A thermoelectric conversion module comprising: electrodes arranged on its high-temperature side and low-temperature side; and P-type and N-type thermoelectric conversion elements connected to the electrodes via a bonding layer; wherein an area where the high-temperature-side electrode is connected to an end face of the P-type or N-type thermoelectric conversion element is smaller than an area where the low-temperature-side electrode is connected to an end face of the P-type or N-type thermoelectric conversion element. For this reason, an incision part is formed by removing the outer periphery of the high-temperature-side bonded part of each thermoelectric conversion element or a portion of the high-temperature-side electrode facing the outer periphery of the high-temperature-side bonded part of each thermoelectric conversion element.

### TECHNICAL FIELD

The present invention relates to a thermoelectric conversion module that converts heat into electricity.

### BACKGROUND ART

For example, the thermoelectric conversion module attached to a pipe of an industrial furnace such as a blast furnace or an incinerator or an exhaust pipe of an automobile is used under a high-temperature environment of 300 to 600° C. Under such an operating environment of the thermoelectric conversion module, in a bonding between the thermoelectric conversion element and an electrode, stress is generated at the bonding due to a thermal expansion. difference between the thermoelectric conversion element and the electrode, which leads to a concern about a fracture inside the bonding or the thermoelectric conversion element.

One example of the background art of the bonding structure of such a thermoelectric conversion element may be Japanese Unexamined Patent Application Publication No. 2012-204623 (Patent Literature 1). This literature describes, “On an electrode plate in the thermoelectric conversion module, a pair of electrode-side bonding surfaces spaced from each other and a coupling that couples the electrode-side bonding surfaces, respectively. Moreover, each thermoelectric conversion element is in a shape of a prism, with each element-side bonding surface having a rectangular shape. Each electrode-side bonding surface and each element-side bonding surface are homothetic, each electrode-side bonding surface being made to have a smaller area than each element-side bonding surface. Each electrode-side bonding surface and each element-side bonding surface are joined by soldering, and each electrode-side bonding surface and each element-side bonding surface are joined by soldering. These features allow the solder to be formed thinner in all the corners C of the thermoelectric conversion element and its periphery L than other areas.” (See “Abstract”).

### CITATION LIST

### Patent Literature

Patent Literature 1: Japanese Unexamined Patent Application Publication No. 2012-204623

### SUMMARY OF INVENTION

### Technical Problem

Patent Literature 1 describes the structure of the thermoelectric conversion module. However, although the thermoelectric conversion module according to Patent Literature 1 describes that the thermoelectric conversion module can relax the stress generated at the element, it cannot relax the strain on the solder. With such a thermoelectric conversion module, it is difficult to secure the thermal fatigue resistance reliability of the bonding because, due to the thin solder bonding at its end, the strain is concentrated in the solder once the temperature change arises.

In an environment involving to large temperature difference between an operating state and a non-operating state such as in an automobile, it is essential to reduce thermal stress generated between the electrode and the element.

It is therefore an object of the present invention to provide a thermoelectric conversion module that can achieve relaxation of the stress and the strain in the element and at the bonding in the vicinity of the bonding between the element and the high-temperature-side electrode where the stress is concentrated.

### Solution to Problem

To achieve the aforementioned object, the present invention employs the configurations described in the appended claims.

The present invention includes a plurality of means for solving the above problems. One example of the thermoelectric conversion module according to the present invention would be a thermoelectric conversion module comprising: electrodes arranged on its high-temperature side and low-temperature side; and P-type and N-type thermoelectric conversion elements connected to the electrodes via a bonding layer; wherein the P-type thermoelectric conversion element includes an end face connected to the high-temperature-side electrode, an end face connected to the low-temperature-side electrode, and a side face connecting the end face connected to the high-temperature-side electrode and the end face connected to the low-temperature-side electrode, an area of the end face connected to the high-temperature-side electrode is made smaller than an area of the end face connected to the low-temperature-side electrode, and the side face includes a parallel portion formed in parallel and a small-diameter portion with its cross-sectional area reducing toward the end face connected to the high-temperature-side electrode.

The thermoelectric conversion module according to the present invention may be manufactured by removing a circumference of the bonding on the high temperature side of the P-type or N-type thermoelectric conversion element, thereby forming a cutout.

Another example of the thermoelectric conversion module according to the present invention would be a thermoelectric conversion module comprising: electrodes arranged on its high-temperature side and low-temperature side; and P-type and N-type thermoelectric conversion elements connected to the electrodes via a bonding layer; wherein an area where the high-temperature-side electrode is connected to an end face of the P-type or N-type thermoelectric conversion element is smaller than an area where the low-temperature-side electrode is connected to an end face of the P-type or N-type thermoelectric conversion element.

The thermoelectric conversion module according to the present invention may be manufactured by removing a portion of the high-temperature-side electrode facing the circumference of the bonding on the high temperature side of the thermoelectric conversion element.

### Advantageous Effects of Invention.

According to the present invention, in a thermoelectric conversion module, it is possible to relax stress and strain generated in an element and at a bonding and also inhibit a crack in the element and a rupture of the bonding in the vicinity of the bonding between the element/electrode where the stress is concentrated.

### BRIEF DESCRIPTION. OF DRAWINGS

FIG. 1 A side view extracting a vicinity of an element of a thermoelectric conversion module according to a first embodiment of the present invention.

FIG. 2A A schematic showing a cutout of a thermoelectric conversion element according to the first embodiment of the present invention.

FIG. 2B A schematic showing a cutout of a thermoelectric conversion element according to the first embodiment of the present invention.

FIG. 3A A schematic showing an effect of stress reduction by a cutout width of the thermoelectric conversion element according to the first embodiment of the present invention.

FIG. 3B A schematic showing an effect of stress reduction by a cutting depth of the thermoelectric conversion element according to the first embodiment of the present invention.

FIG. 4A A flow side view showing a flow of a method of manufacturing a thermoelectric conversion element assembly according to the first embodiment of the present invention.

FIG. 4B A flow side view showing a flow of a method of manufacturing a thermoelectric conversion element assembly according to the first embodiment of the present invention.

FIG. 4C A flow side view showing a flow of a method of manufacturing a thermoelectric conversion element assembly according to the first embodiment of the present invention.

FIG. 5 A perspective view of an exemplary thermoelectric conversion module according to the first embodiment of the present invention.

FIG. 6A A plan view extracting a shape of the element on a high-temperature bonding side of the thermoelectric conversion module according to the first embodiment of the present invention.

FIG. 6B A plan view extracting a shape of the element on a high-temperature bonding side of the thermoelectric conversion module according to a second embodiment of the present invention.

FIG. 6C A plan view extracting a shape of the element on a high-temperature bonding side of the thermoelectric conversion module according to a third embodiment of the present invention.

FIG. 7 A side view extracting the vicinity of the element of the thermoelectric conversion module according to the fourth embodiment of the present invention.

FIG. 8 A side view extracting the vicinity of the element of the conventional thermoelectric conversion module.

### DESCRIPTION OF EMBODIMENTS

Hereinbelow, embodiments of the present invention are described with reference to drawings. It is noted that, in figures illustrating the embodiments, elements having the same function are denoted by the same designations and reference numerals, and repeated description thereof is omitted.

### First Embodiment

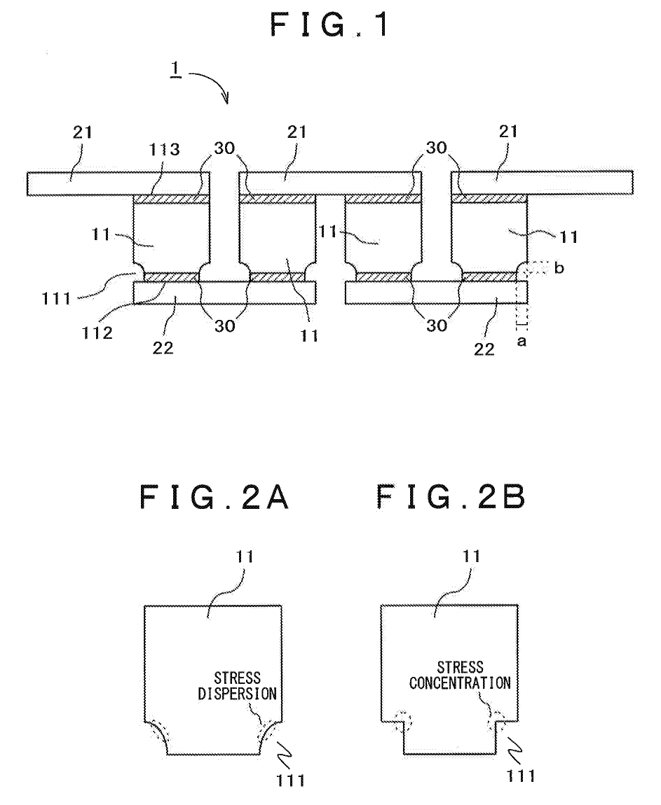

FIG. 1 shows a side view extracting a vicinity of an element of a thermoelectric conversion module according to a first embodiment of the present invention. In FIG. 1, thermoelectric conversion elements 11 including a P-type thermoelectric conversion element and an N-type thermoelectric conversion element are bonded to a low-temperature-side electrode 21 and a high-temperature-side electrode 22 by a bonding material 30. A cutout 111 is formed at a circumference of each thermoelectric conversion element 11 on the side of the high-temperature-side electrode 22 to have a structure in which a high-temperature-side element bonding area 112 is smaller than a low-temperature-side element bonding area 113. That is, each of the P-type and N-type thermoelectric conversion elements 11 has an end face connected to the high-temperature-side electrode 22, an end face connected to the low-temperature-side electrode 21, and a side face connecting the end face connected to the high-temperature-side electrode and the end face connected to the low-temperature-side electrode, the area 112 of the end face connected to the high-temperature-side electrode is made smaller than the area 113 of the end face connected to the low-temperature-side electrode, and it includes a parallel portion in which the side face is formed in parallel and a small-diameter portion with its cross-sectional area reducing toward the end face connected to the high-temperature-side electrode.

The thermoelectric conversion module uses the Seebeck effect in which, by applying a temperature difference between the side faces of the P-type and N-type thermoelectric conversion elements, electrons are made to transfer to generate an electric current. The thermoelectric conversion module has a function of converting heat into electricity by this electron transfer. FIG. 1 is a view in which the top face has a lower temperature and the bottom face has a higher temperature. By bonding the P-type thermoelectric conversion element to the N-type thermoelectric conversion element in series, the current forms an electric circuit. A thermoelectric conversion element assembly 1 is constituted by bonding a plurality of thermoelectric conversion element thus connected in series in a planar form or a linear form.

An optimal material of the thermoelectric conversion element 11 varies depending on the environmental temperature at which the module is used, including silicon-germanium system, iron-silicon system, bismuth-tellurium system, magnesium-silicon system, cobalt-antimony system, bismuth-antimony system, Heusler alloy system, half-Heusler alloy system, and the like.

Because there must be a temperature difference between the top and bottom surfaces in the thermoelectric conversion module 1 as described above, it is conceived that the stress should concentrate on the bonding between the element and electrode, especially the bonding on the high-temperature side, of the thermoelectric conversion element 11 due to the heat load at the time of bonding and the temperature change at the time of operation. There is a problem that a crack may occur to the element or bonding and thereby greatly reducing the bonding reliability when the stress is generated in the bonding and exceeds the fracture stress of the bonding.

Therefore, hard solder, solder, and soft solder may be often used as the bonding material for bonding the thermoelectric conversion element and the electrode. In the case of the hard solder, its bonding temperature is as high as 600 to 800° C., which requires a structure of reducing the stress generated in the bonding during a cooling step of the bonding process. In the case of the soft solder, the stress due to the bonding process can be reduced more than the case of the hard solder because its bonding temperature is 300° C. or lower, but the application is limited to the low-temperature type of the thermoelectric conversion module because its melting point is 300° C. or lower.

It is desirable that the low-temperature-side electrode 21 and the high-temperature-side electrode 22 are made of nickel, molybdenum, titanium, iron, copper, manganese, tungsten, or an alloy composed primarily of any one of these metals. Especially, if a linear expansion coefficient of the thermoelectric conversion element material is different from the thermoelectric conversion element of the electrode, the stress can be generated in the vicinity of the bonding when the temperature change occurs, and therefore the bonding reliability can be improved more by selecting such a material of which linear expansion coefficient is less different from that of the thermoelectric conversion element as the electrode with the aim of reducing the stress in the vicinity of the bonding. It is desirable that the bonding material 30 is aluminum, nickel, tin, copper, zinc, germanium, magnesium, gold, silver, indium, lead, bismuth, tellurium, or an alloy composed primarily of any one of these metals.

Although the linear expansion coefficient of the silicon-germanium element as an example of the thermoelectric conversion element 11 is 4.5 ppm/° C. and the linear expansion coefficient of the silicon-magnesium element is 15.5 ppm/° C., in this embodiment, the linear expansion coefficient of the thermoelectric conversion element 11 is described as α ppm/° C. Similarly, although the materials of the low-temperature-side electrode 21 and the high-temperature-side electrode 22 can be molybdenum (linear expansion coefficient of 5.8 ppm/° C.), nickel (linear expansion coefficient of 15.2 ppm/° C.), and the like, in this embodiment, it is described as a material having a linear expansion coefficient of β ppm/° C.

In the thermoelectric conversion module, because only the high-temperature-side electrode 22 is heated, a stretch is caused in the thermoelectric conversion element 11 and the high-temperature-side electrode 22 on the high-temperature side associated with the temperature increase. The length of the stretch of the thermoelectric conversion module 1 and the high-temperature-side electrode 22 when the temperature increases can be expressed as, assuming a distance from the center of the bonding as L, α×ΔT×L and β×ΔT×L, respectively. The difference of the stretch |(α-β)×ΔT×L| may be the cause of the stress generated in the vicinity of the bonding. Because the material of the thermoelectric conversion element 11 and the environmental temperature to be used can be determined based on the target product, it is true that α, β, and ΔT are determined based on the product. Therefore, in order to reduce the stress generated in the high-temperature-side electrode 22, it is effective to shorten the distance L from the center of the bonding. According to this embodiment, as shown in FIG. 1, the distance L from the center of the bonding is reduced by removing the circumference of the bonding on the high-temperature side of the thermoelectric conversion element to form the cutout 111 so that the high-temperature-side bonding area 112 is made smaller than the low-temperature-side bonding area 113, whereby the bonding reliability can be improved. On the other hand, the low-temperature-side electrode 21 is cooled at the low-temperature-side bonding, and therefore its temperature increase is suppressed compared with the high-temperature-side bonding. The bonding area is ensured on the low-temperature side because the bonding area should be as large as possible in order to improve the thermoelectric conversion characteristics.

The high-temperature-side bonding area 112 can be determined by the removed length a of the circumference (FIG. 1), and, in order to prevent a crack in the thermoelectric conversion element 11, the value a may be determined by deriving the temperature difference ΔT from the environmental temperature used and the stress generated in the element based on the linear expansion coefficient difference α-β between the thermoelectric conversion element 11 and the high-temperature-side electrode 22, so that the stress value may be smaller than the fracture stress of the thermoelectric conversion element 11.

In this embodiment, the shape of the high-temperature bonding side of the bonding material 30 is illustrated to be the same size as the high-temperature-side bonding area, but the present invention is not limited thereto.

The removal of the circumference may be performed using a dicing blade or laser process when dicing the element, or may be performed after being divided into elements.

FIGS. 2A and 2B show the shapes of the cutout 111 formed by removing the circumference of the bonding on the high-temperature side of the thermoelectric conversion element 11. In a case where the cutout 111 has a right-angle portion as shown in FIG. 2B, the stress concentrates on the right-angle portion and tends to cause a crack rupture. By curving the cutout to be recessed toward the thermoelectric conversion element as shown in FIG. 2A, the stress is dispersed and prevents a crack or rupture.

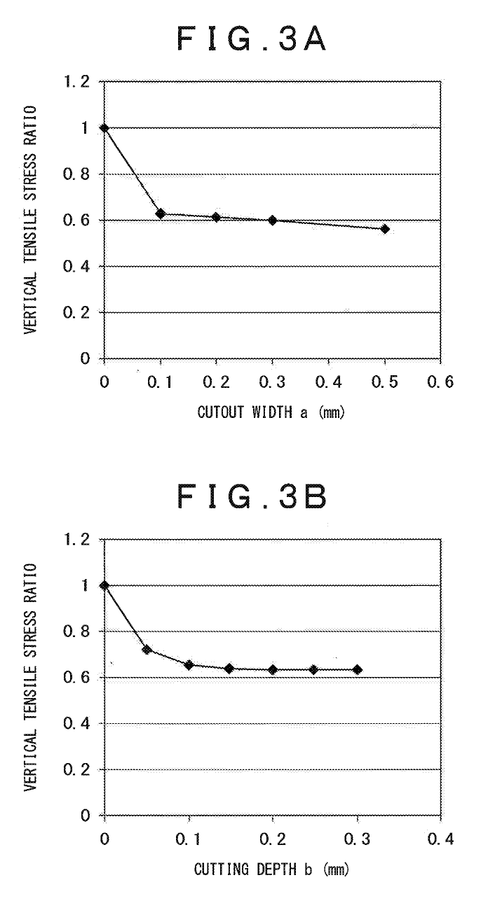

An example of the effect of the lengths a and b of the cutout in FIG. 1 is now described with reference to FIGS. 3A and 3B. FIG. 3A shows the cutout width a (mm) on the horizontal axis, and a stress ratio assuming a vertical tensile stress of the thermoelectric conversion element side face having no cutout as 1 on the vertical axis. In this simulation, a two-dimensional model is formed by bonding a thermoelectric conversion element having a height of 2.3 mm between the electrodes with 0.05 mm thick bonding material interposed therebetween, and the stress generated on the thermoelectric conversion element side face in the vertical direction when the temperature is reduced from 600° C. to 25° C. is evaluated. It can be seen from FIG. 3A that ensuring 0.1 mm for the cutout width a can reduce the stress value approximately by 40%. Making the cutout width too large will reduce the bonding area between the thermoelectric conversion element 11 and the high-temperature-side electrode 22, which influences the thermoelectric conversion characteristics. From the above, it is desirable that the cutout width a should be 0.1 mm or larger, and equal to or smaller than a length that allows the bonding area between the thermoelectric conversion element 11 and the high-temperature-side electrode 22 to ensure 50% or more of the bonding area between the thermoelectric conversion element 11 and the low-temperature-side electrode 21. In addition, the area of the end face connected to the high-temperature-side electrode is suitably 50 to 95% of the area of the end face connected to the low-temperature-side electrode.

FIG. 3B shows the cutting depth b (mm) on the horizontal axis, and the stress ratio assuming the vertical tensile stress of the thermoelectric conversion element side face having no cutout as 1 on the vertical axis. The simulating conditions are same as those in FIG. 3A. It can be seen from FIG. 3B that ensuring 0.05 mm for the cutting depth b (mm) can reduce the stress value approximately by 30%. Moreover, making the cutout depth b too large will reduce the volume of the thermoelectric conversion element 11, which influences the thermoelectric conversion characteristics. From these above, it is desirable that the cutting depth b should be 0.05 mm or larger, and equal to or smaller than 50% of the height of the thermoelectric conversion element 11.

For comparison, FIG. 8 shows the conventional heat conversion module having no cutout. In the heat conversion module having no cutout, the stress is applied to the circumferential portion of the thermoelectric conversion element 11 bonded with the high-temperature-side electrode 22 encircled by a dotted line.

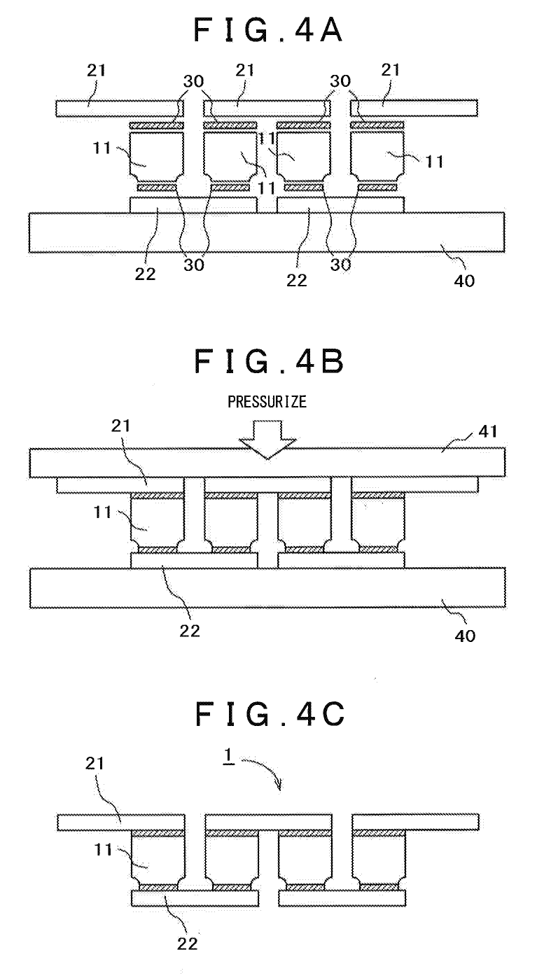

FIGS. 4A to 4C are flow side views showing a flow of a method of manufacturing the thermoelectric conversion element assembly according to the first embodiment of the present invention. It should be noted that the description of the elements already described with reference to FIG. 1 is omitted here.

First, as shown in FIG. 4A, the high-temperature-side electrode 22 is placed on a support tool 40. In this assembly process, the support tool 40 can be made of any material, that will not melt in the bonding process, such as ceramic and metal, and it is desirable to use a material that will not react with the bonding material 30 or form a non-reactive layer on the surface, thereby inhibiting any reaction. Next, on the high-temperature-side electrode 22, the bonding material 30 and the thermoelectric conversion element 11 are aligned and plated in this order. The bonding material 30 is again placed on each thermoelectric conversion element, and the low-temperature-side electrode 21 is placed on the thermoelectric conversion element 11. The description is given herein assuming the bonding material 30 as a metallic foil, where the thickness of the bonding material 30 is preferably 1 to 500 μm. They may be placed collectively using a tool (not shown) or separately.

The cutout in the thermoelectric conversion element can be made by using a dicing blade, a laser process, or a wire saw when dividing a thermoelectric element wafer into pieces, or by using a cutting process or a grinding process after the wafer is divided into pieces. As an example of forming the cutout when dividing the thermoelectric element wafer into pieces, the method using the dicing blade is described below. First, a grooving process is performed on a dicing line on the thermoelectric element wafer using a thick blade to form the cutout. Then the wafer is diced along the same line using a thin blade to divide it into pieces, thereby forming the thermoelectric conversion element 11 having the cutout. Although the example of dicing the wafer using the thick blade and the thin blade on the same side is described above, the thermoelectric element wafer may be diced both on the front and the rear. Furthermore, the wafer may be diced in advance using the thin blade and then the cutout may be formed using the thick blade. Although the dicing blade is used here as an example, a similar process can be performed varying the output power in the case of the laser process or varying the wire diameter in the case of the wire saw.

Next, as shown in FIG. 4B, the bonding material 30 is fused to bond the low-temperature-side electrode 21 with the thermoelectric conversion element 11 and the high-temperature-side electrode 22 with the thermoelectric conversion element 11 with the bonding material 30 interposed therebetween by applying pressure and heat from a pressurizing tool 41 from the above. The bonding is preferably performed with 0.12 kPa or higher load applied to the thermoelectric conversion element. After that, as shown in FIG. 4C, the thermoelectric conversion module 1 is formed by removing it from the pressurizing tool 41 and the support tool 40. In this manner, the bonding process is similar to the conventional process, and there is no need of a new process.

Although the process of collectively bonding the bonding material 30 on the upper and lower faces is shown in the description of FIG. 4A to 4C, it is also possible to bond either one in advance and the other afterwards. For example, at the step shown in FIG. 4A, the thermoelectric conversion module 1 may also be formed by placing only the bonding material 30 on the side of the support tool 40 and the thermoelectric conversion element 11, heating the lower support tool 40 and fusing the bonding material 30 to bond the thermoelectric conversion element 11 and the high-temperature-side electrode 22, and then bonding the upper face of the thermoelectric conversion element 11 and the low-temperature-side electrode 21 using the bonding material 30.

The pressurizing force is set to 0.12 kPa or higher here in order to prevent the thermoelectric conversion element 11 from inclining at the time of bonding and to eject the bonding material 30 used out of an interfaces between the thermoelectric conversion element 11 and the low-temperature-side electrode 21 and the high-temperature-side electrode 22 as much as possible. An upper limit of the pressurizing force is not particularly specified, but it should be lower than the crushing strength of the element so that the element will not be broken. Specifically, it may, be about 1000 MPa or lower, but the pressure in the order of a few MPa can achieve a sufficient effect in this embodiment.

The bonding atmosphere has only to be a non-oxidizing atmosphere, and specifically a vacuum atmosphere, a nitrogen atmosphere, a nitrogen-oxygen mixture atmosphere, and the like can be used.

Although this embodiment uses the metallic foil as the bonding material 30, other materials such as powder or alloy powder can also be used as the bonding material 30. In such a case, as the bonding material 30, a single type of powder may be used, layers formed of different types of powder may be laminated, or a mixture of these different types of powder may be used. When using such powder, a compact of powder alone may be arranged only in a location of bonding the thermoelectric conversion element 11 in advance, or the powder may be applied only to the location of bonding the thermoelectric conversion element, or the powder made into the form of paste using resin or the like may also be applied to the location of bonding the thermoelectric conversion element. The manufacturing process can be further simplified, because the step of arranging the foil can be eliminated by applying the powder in advance.

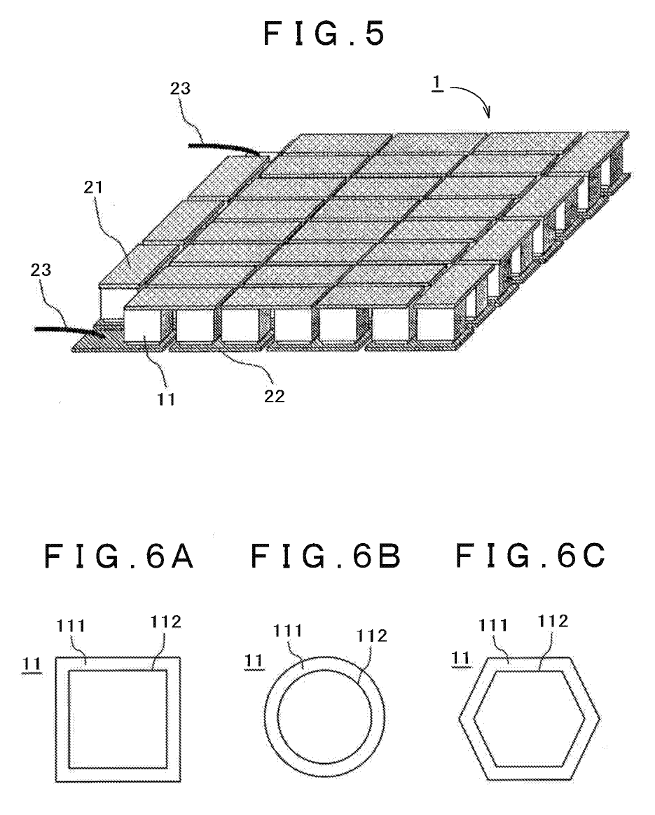

FIG. 5 shows a perspective view of an example of the thermoelectric conversion module according to the first embodiment of the present invention, in which 62 thermoelectric conversion elements are arranged and bonded in a latticed pattern. 23 donates a lead-out wiring, but other elements are already described in FIG. 1 and the description thereof is omitted. The lead-out wiring 23 is used for extracting electricity generated by the thermoelectric conversion element, and may use any material as long as it can conduct electricity. Based on the process shown in FIG. 4, the thermoelectric conversion module shown in FIG. 5 is fabricated. This thermoelectric conversion module may be used as encapsulated in a case or as it is. As shown in FIG. 5, the thermoelectric conversion elements 11 are connected alternately by the low-temperature-side electrodes 21 and the high-temperature-side electrodes 22 to be electrically connected in series. The lead-out wirings 23 are formed from both ends of the series connection to take an electromotive force to the outside. In FIG. 5, each thermoelectric conversion element 11 is illustrated as a square prism, the shape of which seen from the high-temperature-side electrode is as shown in FIG. 6A. The shape of the thermoelectric conversion element is not limited to the square prism but it may be any columnar shape such as a triangular prism, a polygonal prism, a circular column, or an oval column.

By using a structure in which the bonding area between the thermoelectric conversion element 11 and the high-temperature-side electrode 22 is made smaller than the bonding area between the thermoelectric conversion element 11 and the low-temperature-side electrode 21 as shown in the first embodiment such as the structure in which the circumference is removed, it is possible to suppress the thermal stress generated between the thermoelectric element and the electrode in a high-temperature environment or a temperature-varying environment, thereby ensuring high reliability even in the actual operating environment.

As the structure in which the bonding area between the thermoelectric conversion element and the high-temperature-side electrode is made smaller than the bonding area between the thermoelectric conversion element and the low-temperature-side electrode, it is conceivable that the thermoelectric conversion element is made to have a conical shape to obtain the bonding area with the high-temperature-side electrode smaller than the bonding area with the low-temperature-side electrode. However, making the thermoelectric conversion element in the conical shape will reduce the volume of the element and thus reduce the power generation efficiency. According to this embodiment, because the thermoelectric conversion element is constituted by the parallel portion in which the side face is formed in parallel and the small-diameter portion with its cross-sectional area reducing toward the end face connected to the high-temperature-side electrode, it is possible to suppress the thermal stress generated between the thermoelectric conversion element and the electrode without reducing the power generation efficiency,

### Second Embodiment

FIG. 6B is a plan view extracting the element shape of the thermoelectric conversion module on the high-temperature bonding side according to a second embodiment of the present invention. Although the first embodiment employs the thermoelectric conversion element 11 in the shape of the square prism as shown in FIGS. 5 and 6A, this embodiment employs the circular column shape. By employing such a circular column shape, the stress generated in the circumferential portion can be homogenized, whereby an improvement in the bonding reliability can be expected. Even when using the thermoelectric conversion element of the shape described in the second embodiment, the thermoelectric conversion module can be fabricated in the process shown in FIG. 4, and thus there is no need of a new process for the element shape in this embodiment.

### Third Embodiment

FIG. 6C is a plan view extracting the element shape of the thermoelectric conversion module on the high-temperature bonding side according to a third embodiment of the present invention. Although the first embodiment employs the thermoelectric conversion element 11 in the shape of the square prism as shown in FIGS. 5 and 6A, the third embodiment employs a hexagonal prism shape. By employing such a hexagonal prism shape, the stress prone to concentrate on the corners can be dispersed, whereby the improvement in the bonding reliability can be expected. Moreover, a larger number of elements can be diced from a single wafer, which enables reduction of the unit price of the element. Although the hexagonal prism is described herein as an example of the polygonal prism, any other polygonal prism can be used. Even when using the thermoelectric conversion element of the shape described in the third embodiment, the thermoelectric conversion module can be fabricated in the process shown in FIG. 4, and thus there is no need of a new process for the element shape in this embodiment.

### Fourth Embodiment

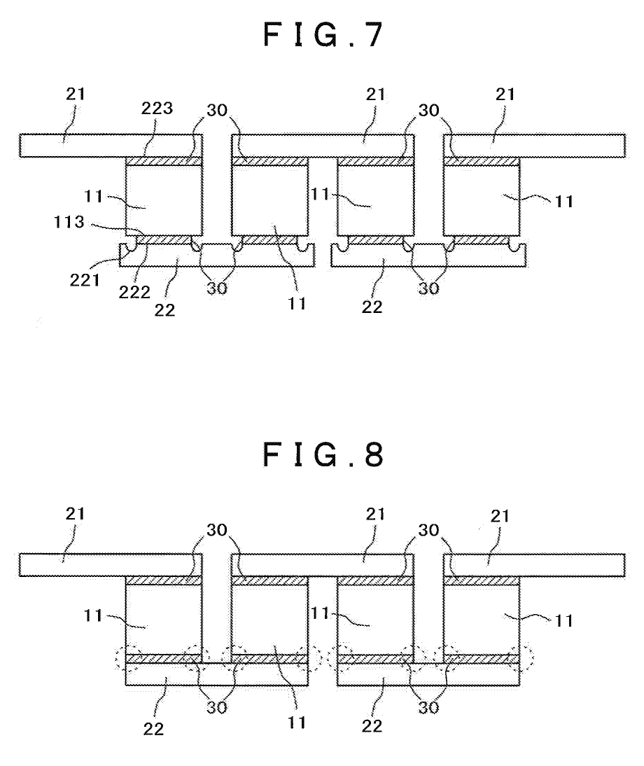

FIG. 7 is a side view extracting the vicinity of the elements in the thermoelectric conversion module according to a fourth embodiment of the present invention. For the elements already described with reference to FIG. 1, the description thereof is omitted. In this embodiment, a cutout is formed in the high-temperature-side electrode 22. That is, a portion of the high-temperature-side electrode 22 that faces the circumference of the bonding on the high-temperature side of the thermoelectric conversion element 11 is removed to form a cutout 221. In this embodiment, the cutout 221 is formed with a curvilinear surface recessed toward the high-temperature-side electrode 22. By making a high-temperature-side electrode bonding area 222 smaller than a low-temperature-side electrode bonding area 223 by forming the thermoelectric conversion module 1 using the high-temperature-side electrode 22 having the cutout 221, it is possible to reduce the stress generated in the vicinity of the bonding, thereby obtaining the same effect as that of the first embodiment. Moreover, because the bonding area is adjusted on the electrode side, there is no need of processing the thermoelectric conversion element 11.

There is no limit on the shape of the cutout 221 as long as the high-temperature-side electrode bonding area 222 is controlled to be smaller than the low-temperature-side electrode bonding area 223.

Although FIG. 7 shows only the side view, the shape of the thermoelectric conversion element 11 may be any one of the square prism, the circular column, or the polygonal prism as shown in the first to third embodiments. Furthermore, the manufacturing process of the thermoelectric conversion module 1 is feasible with the same process as the first embodiment shown in FIG. 4

### INDUSTRIAL APPLICABILITY

The present invention can relax the stress and strain generated in the element and the bonding in the vicinity of the bonding between the element and the electrode of the thermoelectric conversion module where the stress is concentrated, thereby inhibiting a crack in the element and a rupture of the bonding. Thus, the thermoelectric conversion module according to the present invention can be applied to electric power generation in a high-temperature environment by, for example, being attached to a pipe of an industrial furnace, such as a blast furnace and an incinerator, or an exhaust pipe of an automobile.

### LIST OF REFERENCE SIGNS

1 Thermoelectric conversion module
11 Thermoelectric conversion element
21 Low-temperature-side electrode
22 High-temperature-side electrode
23 Lead-out wiring
30 Bonding material
40 Support tool
41 Pressurizing tool
111 Cutout
112 High-temperature-side element bonding area
113 Low-temperature-side element bonding area
221 Cutout
222 High-temperature-side electrode bonding area
223 Low-temperature-side electrode bonding area

1. A thermoelectric conversion module comprising:
electrodes arranged on its high-temperature side and low-temperature side; and
P-type and N-type thermoelectric conversion elements connected to the electrodes via a bonding layer;
wherein each of the P-type and N-type thermoelectric conversion elements includes an end face connected to the high-temperature-side electrode, an end face connected to the low-temperature-side electrode, and a side face connecting the end face connected to the high-temperature-side electrode and the end face connected to the low-temperature-side electrode, an area of the end face connected to the high-temperature-side electrode is made smaller than an area of the end face connected to the low-temperature-side electrode, and the side face includes a parallel portion formed in parallel and a small-diameter portion with its cross-sectional area reducing toward the end face connected to the high-temperature-side electrode.

2. A thermoelectric conversion module comprising:
electrodes arranged on its high-temperature side and low-temperature side; and
P-type and N-type thermoelectric conversion elements connected to the electrodes via a bonding layer;
wherein an area where the high-temperature-side electrode is connected to an end face of the P-type or N-type thermoelectric conversion element is smaller than an area where the low-temperature-side electrode is connected to an end face of the P-type or N-type thermoelectric conversion element.

3. The thermoelectric conversion module according to claim 1,
wherein the area of the end face connected to the high-temperature-side electrode or the area where the high-temperature-side electrode is connected to the end face of the P-type or N-type thermoelectric conversion element is 50 to 95% of the area of the end face connected to the low-temperature-side electrode.

4. The thermoelectric conversion module according to claim 1,
wherein a circumference of the bonding on the high temperature side of the P-type or N-type thermoelectric conversion element is removed to form a cutout.

5. The thermoelectric conversion module according to claim 2,
wherein a cutout is formed by removing a portion of the electrode on the high-temperature side facing the circumference of the bonding on the high-temperature side of the thermoelectric conversion element.

6. The thermoelectric conversion module according to claim 4,
wherein the cutout is formed with a curvilinear surface recessed toward the thermoelectric conversion element.

7. The thermoelectric conversion module according to claim 5,
wherein the cutout is formed with a curvilinear surface recessed toward the electrode on the high-temperature side.

8. The thermoelectric conversion module according to claim 6,
wherein a depth of the cutout is 0.05 mm or more and equal to or smaller than 50% of a height of the thermoelectric conversion element, and a length from an end portion of the cutout is 0.1 mm or more and equal to or less than a length ensuring that the bonding area between the thermoelectric conversion element and the high-temperature-side electrode is 50% or more of the bonding area between the thermoelectric conversion element and the low-temperature-side electrode.

9. The thermoelectric conversion module according to claim 4,
wherein the cutout is formed by a cutting process.

10. The thermoelectric conversion module according to claim 4,
wherein the cutout is formed by a grinding process.

11. The thermoelectric conversion module according to claim 4,
wherein the cutout is formed by a dicing process using a dicing blade.

12. The thermoelectric conversion module according to claim 4,
wherein the cutout is formed by a laser process.

13. The thermoelectric conversion module according to claim 1,
wherein the shape of the thermoelectric conversion element is one of a square prism, a circular column, and a polygonal prism.

14. The thermoelectric conversion module according to claim 1,
wherein the P-type or N-type thermoelectric conversion element is made of a combination of silicon-germanium system, iron-silicon system, bismuth-tellurium system, magnesium-silicon system, lead-tellurium system, cobalt-antimony system, bismuth-antimony system, Heusler alloy system, and/or half-Heusler alloy system.

15. The thermoelectric conversion module according to claim 1,
wherein a plurality of P-type and N-type thermoelectric conversion elements are arranged and bonded in a latticed pattern, and some or all of the plurality of P-type and N-type thermoelectric conversion elements are electrically connected in series.

16. The thermoelectric conversion module according to claim 2,
wherein the area where the high-temperature-side electrode is connected to the end face of the P-type or N-type thermoelectric conversion element is 50 to 95% of the area of the end face connected to the low-temperature-side electrode.

17. The thermoelectric conversion module according to claim 5,
wherein the cutout is formed by a cutting process.

18. The thermoelectric conversion module according to claim 5,
wherein the cutout is formed by a grinding process.

19. The thermoelectric conversion module according to claim 5,
wherein the cutout is formed by a dicing process using a dicing blade.

20. The thermoelectric conversion module according to claim 5,
wherein the cutout is formed by a laser process.
